(19) United States
(12) Patent Application Publication
(10) Pub. No.: US 2006/0127815 A1
(43) Pub. Date: Jun. 15, 2006

(54) Pattern forming method and method of manufacturing semiconductor device

(76) Inventors: Yasuhiko Sato, Yokkaichi-shi (JP); Yasunobu Onishi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/296,480

(22) Filed: Dec. 8, 2005

(30) Foreign Application Priority Data
Dec. 9, 2004 (JP) 2004-357073

(51) Int. Cl. G03F 7/00

(52) U.S. Cl. 430/312; 430/313

(57) ABSTRACT

According to an aspect of the invention, there is provided a pattern forming method comprising forming a first resist film on a film to be worked formed on a semiconductor substrate, forming a second resist film on the first resist film, forming a resist pattern from the second resist film, forming an overcoat film containing a metal element or a semi-conducting element on the resist pattern, insolubilizing, in a predetermined solvent, a portion of the overcoat film at a predetermined distance from an interface between the overcoat film and the resist pattern, removing, with the solvent, a portion of the overcoat film soluble in the solvent to form an overcoat film pattern, transferring the overcoat film pattern to the first resist film to form a lower-layer resist film pattern, and transferring the lower-layer resist film pattern to the film to be worked to form a pattern on the film.

### CROSS-REFERENCE TO RELATED APPLICATIONS

This application is based upon and claims the benefit of priority from prior Japanese Patent Application No. 2004-357073, filed Dec. 9, 2004, the entire contents of which are incorporated herein by reference.

### BACKGROUND OF THE INVENTION

1. Field of the Invention

The present invention relates to a pattern forming method in a step of manufacturing a semiconductor device, and a method of manufacturing the semiconductor device.

2. Description of the Related Art

A method of manufacturing a semiconductor device includes many steps of depositing a plurality of substances on a silicon wafer to pattern the substances into desired patterns. When patterning a film to be worked, first a photosensitive substance called a resist is deposited on the film to be worked on the wafer, a resist film is formed, and a predetermined region of this resist film is exposed. Subsequently, an exposed or unexposed portion of the resist film is removed by a developing treatment to form a resist pattern. Furthermore, the film to be worked is dry-etched using this resist pattern as an etching mask.

As an exposure light source, ultraviolet light is used such as KrF excimer laser or ArF excimer laser from a viewpoint of throughput. However, with miniaturization of LSI, a necessary resolution is not more than a wavelength, and an exposure process tolerance such as an exposure tolerance or a focus tolerance is lacking. To compensate for these process margins, it is effective to reduce a film thickness of resist and enhance the resolution. However, there occurs a problem that the resist film thickness required for etching the film to be worked cannot be secured.

To solve this problem, there is investigated a process to successively form a lower-layer resist film and a silicon-containing resist on the film to be worked, and transfer to the lower-layer resist film a resist pattern formed by subjecting the silicon-containing resist to pattern exposure. However, in this process, it is impossible to form on the film to be worked a space or a hall pattern which is finer than an optical image formed on the resist pattern. Since the silicon-containing resist contains silicon, the resist is inferior to a resist that does not contain silicon in resolution.

Moreover, in Jpn. Pat. No. 2723260, a fine pattern forming method is disclosed in which a side surface of an open hole of a first resist is coated with a second resist, and reacted. Thereafter, the second resist is removed to reduce a size of the open hole.

In Jpn. Pat. No. 3071401, there are disclosed a fine pattern forming material by which a first resist pattern is coated with a water-soluble resin, and cross-linked with acid to remove a non-bridged portion, a method of manufacturing a semiconductor device using this material, and a semiconductor device.

### BRIEF SUMMARY OF THE INVENTION

According to an aspect of the invention, there is provided a pattern forming method comprising: forming a first resist film on a film to be worked formed on a semiconductor substrate; forming a second resist film on the first resist film; forming a resist pattern from the second resist film; forming an overcoat film containing a metal element or a semi-conductive element on the resist pattern; insolubilizing, in a predetermined solvent, a portion of the overcoat film at a predetermined distance from an interface between the overcoat film and the resist pattern; removing, with the solvent, a portion of the overcoat film soluble in the solvent to form an overcoat film pattern; transferring the overcoat film pattern to the first resist film to form a lower-layer resist film pattern; and transferring the lower-layer resist film pattern to the film to be worked to form a pattern on the film to be worked.

According to another aspect of the invention, there is provided a method of manufacturing a semiconductor device, comprising: forming a first resist film on a film to be worked formed on a semiconductor substrate; forming a second resist film on the first resist film; forming a resist pattern from the second resist film; forming an overcoat film containing a metal element or a semi-conductive element on the resist pattern; insolubilizing, in a predetermined solvent, a portion of the overcoat film at a predetermined distance from an interface between the overcoat film and the resist pattern; removing, with the solvent, a portion of the overcoat film soluble in the solvent to form an overcoat film pattern; transferring the overcoat film pattern to the first resist film to form a lower-layer resist film pattern; and transferring the lower-layer resist film pattern to the film to be worked to form a pattern on the film to be worked, whereby manufacturing the semiconductor device.

### BRIEF DESCRIPTION OF THE SEVERAL VIEWS OF THE DRAWING

FIG. 1 is a sectional view showing a pattern forming treatment procedure which is a manufacturing process of a semiconductor device in the present embodiment;

FIG. 2 is a sectional view showing a pattern forming treatment procedure which is a manufacturing process of the semiconductor device in the present embodiment;

FIG. 3 is a sectional view showing a pattern forming treatment procedure which is a manufacturing process of the semiconductor device in the present embodiment;

FIG. 4 is a sectional view showing a pattern forming treatment procedure which is a manufacturing process of the semiconductor device in the present embodiment;

FIG. 5 is a sectional view showing a pattern forming treatment procedure which is a manufacturing process of the semiconductor device in the present embodiment;

FIG. 6 is a sectional view showing a pattern forming treatment procedure which is a manufacturing process of the semiconductor device in the present embodiment; and

FIG. 7 is a sectional view showing a pattern forming treatment procedure which is a manufacturing process of the semiconductor device in the present embodiment.

### DETAILED DESCRIPTION OF THE INVENTION

An embodiment of the present invention will be described hereinafter with reference to the drawings.

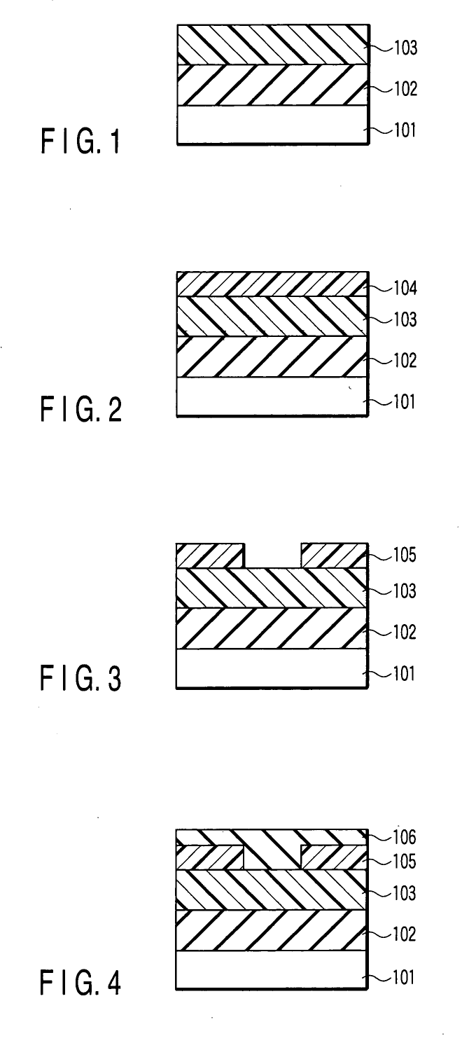

FIGS. 1 to 7 are sectional views showing pattern forming treatment procedures which are manufacturing processes of a semiconductor device in the present embodiment.

First, as shown in FIG. 1, if necessary, a lower-layer resist film 103 is formed on a film 102 to be worked formed on a wafer substrate (silicon substrate, semiconductor substrate) 101 in which a device (MOS transistor) including a diffusion layer (not shown) is formed. The film 102 to be worked is not especially limited, and examples of a material include: a silicon-based insulating film such as a silicon oxide film, a silicon nitride film, a silicon oxynitride film, spin-on glass, or blank material for use in manufacturing a mask; a silicon-based material such as amorphous silicon, polysolicon, or silicon substrate; and a wiring line material such as aluminum, aluminum silicide, copper or tungsten.

A film thickness of the lower-layer resist film 103 is preferably in a range of 20 to 5000 nm. When the film thickness is less than 20 nm, the lower-layer resist film 103 is lost during etching of the film 102 to be worked, and it becomes difficult to work the film 102 to be worked into a desired dimension. When the thickness is larger than 5000 nm, a dimension conversion difference is remarkably generated in transferring the resist pattern to a mask material by a dry etching process.

Moreover, instead of the lower-layer resist film 103, there may be used a anti-reflection film for ultraviolet lithography using KrF excimer laser or ArF excimer laser as a light source. Examples of a coating type anti-reflection film include: AR3, AR5, AR15, or AR19 manufactured by Rohm & Haas Co.; DUV11 manufactured by Brewer Science Co.; and an SiON or SiOC film formed by a CVD or sputtering process. In this case, a film thickness of the coating type anti-reflection film is preferably in a range of 20 to 5000 nm. When the film thickness is less than 20 nm, the lower-layer resist film 103 is lost during the etching of the film 102 to be worked, and it becomes difficult to work the film 102 to be worked into a desired dimension. When the thickness is larger than 5000 nm, a dimension conversion difference is remarkably generated in transferring the resist pattern to the mask material by the dry etching process.

Furthermore, the anti-reflection film may be formed on the lower-layer resist film 103. Even a case where either the lower-layer resist film or the anti-reflection film is not formed is included in the scope of the embodiment of the present invention.

Next, as shown in FIG. 2, the lower-layer resist film 103 is coated with a resist solution, and subjected to a heat treatment to form a resist film 104. When the film thickness of the resist film 104 is reduced, an exposure tolerance at an exposure dose, a focus tolerance, and a resolution can be enhanced. Therefore, the film thickness of the resist film 104 is preferably small as long as the mask material can be etched with a good dimension controllability, and a range of 10 to 10000 nm is preferable.

A type of resist is not especially limited, and a positive or negative resist may be selected and used depending on a purpose. Typical examples of the positive resist include: a resist (IX-770 manufactured by JSR Kabushiki Kaisha) made of naphthoquinone diazide and a novolak resin; and a chemical amplifying resist (APEX-E manufactured by Rohm & Haas Co.) made of a polyvinyl phenol resin protected with t-BOC and an photo-acid-generating agent. Examples of the negative resist include: a chemical amplifying resist (SNR200 manufactured by Rohm & Haas Co.) formed of polyvinyl phenol and melamine resins and a photo acid-generating agent; a resist (RD-2000N manufactured by Hitachi Chemical Co., Ltd.) made of polyvinyl phenol and bisazide compound; and a resist containing polymethacrylate or polyacrylate in a part of a polymer main-chain. The resist solution is applied to the mask material by, for example, a spin-coating process or a dipping process, and thereafter heated to evaporate a solvent, and the resist film 104 is prepared.

The exposure light source is not limited, and examples of the light source include ultraviolet light, X-ray, electron beam, and ion beam. Examples of the ultraviolet light include: a g-line (wavelength=436 nm) or an i-line (wavelength=365 nm) of a mercury lamp; and excimer laser such as XeF (wavelength=351 nm), XeCl (wavelength=308 nm), KrF (wavelength=248 nm), KrCl (wavelength=222 nm), ArF (wavelength=193 nm), or F₂ (wavelength=157 nm).

Moreover, as shown in FIG. 3, after subjecting the resist film 104 to pattern exposure, a developing treatment is performed with an alkali developing liquid such as TMAH or chlorine to form a resist pattern 105. If necessary, an upper-layer anti-reflection film may be formed on an upper layer of the resist film 104 in order to reduce multireflection in the resist generated in a case where exposure is performed. Alternatively, the upper-layer charging preventive film may be formed on the upper layer of the resist film 104 in order to prevent charge-up generated in a case where electron beam exposure is performed.

Next, as shown in FIG. 4, the resist pattern 105 is coated with a solution formed by dissolving in an organic solvent a compound having a metal element or a semi-conducting element having a substituent cross-linked with acid by means of the spin coating process or the like to form an overcoat film 106.

The organic solvent is not especially limited, and examples include: a ketone-based solvent such as acetone, methyl ethyl ketone, methyl isobutyl ketone, or cyclohexanone; a cellosolve-based solvent such as methyl cellosolve, methyl cellosolve acetate, or ethyl cellosolve acetate; an ester-based solvent such as ethyl lactate, ethyl acetate, butyl acetate, or isoamyl acetate; an alcohol-based solvent such as methanol, ethanol, or isopropanyl; ether-based solvent such as dipropylether, or dibutylether; anisole; toluene; xylene; and naphtha.

A content of the metal or semi-conducting element is preferably in a range of 2 to 80 wt % in a solid component of a chemical. When the content is less than 2 wt %, a sufficient etching resistance is not obtained in working the lower-layer resist film 103. When the content exceeds 80 wt %, a coating property deteriorates. Subsequently, when heating is performed using an oven, a hot plate or the like, an acid contained in the resist of the resist pattern 105 is diffused in a certain distance in the overcoat film 106, and the substituent of a portion in which the acid is diffused is cross-linked (acid catalyst reaction). Accordingly, a portion of the overcoat film 106 having a predetermined distance from an interface between the film and the resist pattern 105 is insolubilized in an organic solvent described later. It is to be noted that before this heating step, if necessary, the whole surface of the resist pattern 105 is irradiated with an energy beam to generate the acid from the photo acid generating agent contained in the resist.

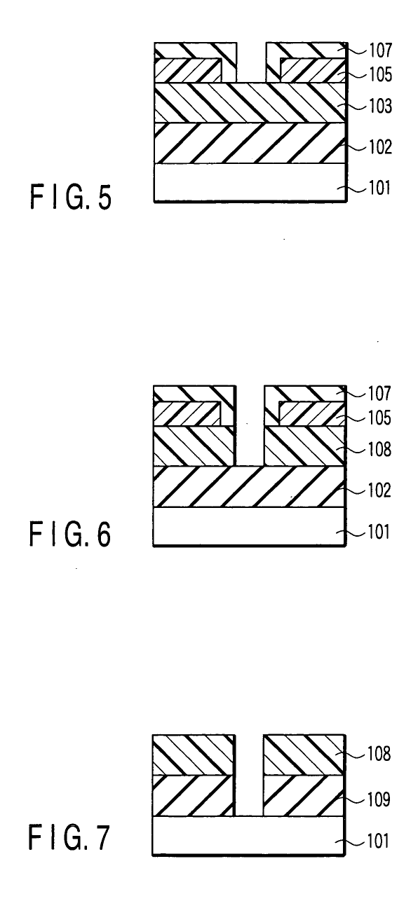

Next, as shown in FIG. 5, a portion of the overcoat film 106 which is not cross-linked is dissolved and removed using the organic solvent to form an overcoat film pattern 107. A certain thickness (the predetermined distance) of the overcoat film pattern 107 floats in the surface and outer periphery of the resist pattern 105. It is possible to use an organic solvent similar to that used in adjusting a solution forming the overcoat film 106. The cross-linked portion of the overcoat film 106 is not easily dissolved owing to the cross-linking. Therefore, when the organic solvent is spread on the overcoat film 106, the portion which is not cross-linked, that is, the portion soluble in the organic solvent can be dissolved and removed.

In the present embodiment, an only constant thickness of the overcoat film 106 from the resist pattern 105 can be left utilizing a property that the acid contained in the resist pattern 105 is diffused by the certain distance by heat. As a result, it is possible to form a narrow space pattern which cannot be formed by the exposure.

Next, as shown in FIG. 6, the overcoat film pattern 107 is transferred to the lower-layer resist film 103 by use of a dry etching process to obtain a lower-layer resist film pattern 108. As an etching process, for example, reactive ion etching, magnetron type reactive ion etching, electron beam ion etching, ICP etching, ECR ion etching or the like is usable, and the process is not especially limited as long as fine working is possible.

As a source gas, it is preferable to use a source gas containing one of an oxygen atom, a nitrogen atom, and a chlorine atom in order to work the mask material with good anisotropy. Since the metal or semi-conducing element is not easily etched with an etchant generated by the source gas, a dry etching resistance of the overcoat film pattern 107 is enhanced, and the lower-layer resist film 103 can be worked with good anisotropy. Typical examples of the source gas include O₂, CO, CO₂, N₂, NH₃, Cl₂, and HCL, and these gases may be mixed. A molecule of H₂, SO₂ or the like containing sulfur may be added to the source gas. Accordingly, it is possible to work the lower-layer resist film 103 with good anisotropy.

Next, as shown in FIG. 7, the lower-layer resist film pattern 108 is transferred to the film 102 to be worked using the dry etching process to form a pattern 109 on the film to be worked. As the etching process, for example, reactive ion etching, magnetron type reactive ion etching, electron beam ion etching, ICP etching, ECR ion etching or the like is usable, and the process is not especially limited as long as fine working is possible.

In the present embodiment, the resist pattern is transferred to the lower-layer resist film 103 having a film thickness required for etching the film 102 to be worked. As a result, it is possible to form the resist pattern 105 whose resist film thickness is thin and which can secure a sufficient exposure margin. The only certain thickness of the overcoat film 106 from the resist pattern 105 can be left utilizing the property that the acid contained in the resist pattern 105 is diffused in the certain distance owing to heat. As a result, it is possible to form the pattern 109 on the film to be worked, which is finer than the resist pattern 105, and it is possible to form the narrow space pattern which cannot be formed by the exposure.

(First Example)

First, a TEOS oxide film (film 102 to be worked) having a film thickness of 700 nm was formed on a wafer substrate 101 by an LPCVD process. Next, after the film was coated with a solution adjusted by dissolving 10 g of a novolak resin having an weight-average molecular weight of 12000 in 90 g of ethyl lactate by a spin coating process, the film was baked at 180° C. for 60 seconds and at 300° C. for 60 seconds to form a lower-layer resist film 103 (see FIG. 1).

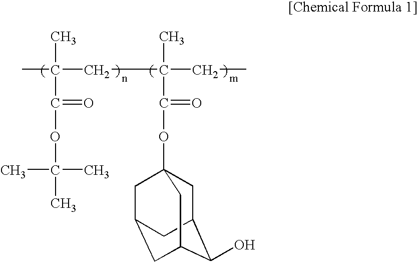

Next, the lower-layer resist film 103 was coated with a resist solution adjusted by dissolving 9 g of a suppressant resin represented by the above chemical formula and having an weight-average molecular weight of 8000 and 1 g of triphenyl sulfonate as an acid forming agent in 90 g of cyclohexanone by use of the spin coating process. Thereafter, the film was baked at 130° C. for 90 seconds to form a resist film 104 (see FIG. 2). A glass transition temperature of the resist film 104 measured by a differential thermal analysis process was 165° C. It is to be noted that in the chemical formula, n:m denotes a composition ratio.

Subsequently, after performing pattern exposure using ArF excimer laser, a developing treatment was performed using 0.21 defined TMAH developing liquid to form a contact hole pattern having a diameter of 150 nm (see FIG. 3).

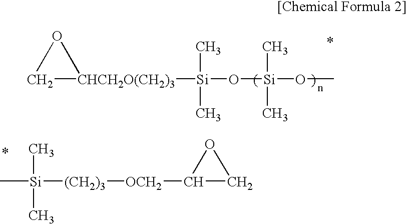

Next, a resist pattern 105 was coated with an overcoat film solution adjusted by dissolving 10 g of an organic compound represented by the above chemical formula and having an weight-average molecular weight of 8000 in 90 g of dibutylether by use of the spin coating process (see FIG. 4). Thereafter, the film was baked at 160° C. for 90 seconds using a hot plate to diffuse in an overcoat film 106 an acid contained in the resist pattern 105, and bridging of a portion in which the acid was diffused was advanced (acid catalyst reaction).

Next, dibutylether was applied to the overcoat film 106 to dissolve and remove a portion of the overcoat film 106 which was not bridged, and a contact hole pattern having a diameter of 90 nm was formed (see FIG. 5).

Next, the lower-layer resist film 103 was etched using a dry etching apparatus on conditions that a flow rate of a source gas was N₂/O₂=10/100 sccm, a vacuum pressure was 10 Torr, and a substrate temperature was 20° C., and a lower-layer resist film pattern 108 was obtained (see FIG. 6). Consequently, the lower-layer resist film pattern 108 could be worked with good anisotropy as shown in FIG. 6.

Next, the film 102 to be worked was etched using the dry etching apparatus on conditions that a flow rate of a source gas was C₄F₈/CO/O₂/Ar=10/10/10/100 sccm, a vacuum pressure was 10 Torr, and a substrate temperature was 20° C., and a contact hole having a diameter of 90 nm was formed in a pattern 109 on the film to be worked (see FIG. 7).

In the present first example, since the overcoat film 106 is formed into a certain thickness on the surface of the resist pattern 105, it is possible to resolve a space pattern which is narrow as much and which cannot be resolved by the exposure. It is possible to work the lower-layer resist film pattern 108 by use of the overcoat film pattern 107 as an etching mask while securing a sufficient etching selective ratio. As a result, it is possible to transfer the resist pattern to the lower-layer resist film 103 having a film thickness required for etching the film 102 to be worked. Even when the film thickness of a resist of the resist pattern 105 is set to be as thin as, for example, 150 nm in order to obtain an exposure margin as in the first example, the film 102 to be worked can be worked.

(Second Example)

First, a TEOS oxide film (film 102 to be worked), and a lower-layer resist film 103 were formed on a wafer substrate 101 in the same manner as in the first example (see FIG. 1).

Next, the lower-layer resist film 103 was coated with a resist solution adjusted by dissolving 9 g of a dissolution inhibition resin represented by the following chemical formula: 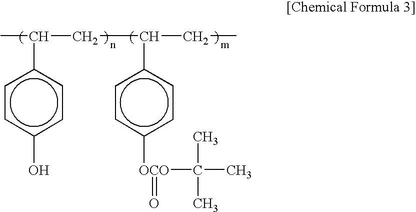
and having an weight-average molecular weight of 8000 and 1 g of an acid forming agent represented by the following chemical formula: 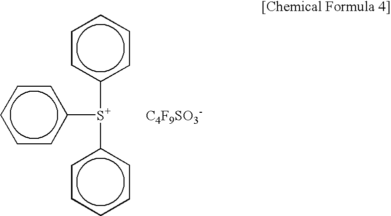
in 90 g of cyclohexanone by use of a spin coating process. Thereafter, the film was baked at 130° C. for 90 seconds to form a resist film 104 (see FIG. 2). It is to be noted that in the above chemical formula, n:m denotes a composition ratio.

Subsequently, after performing pattern exposure using KrF excimer laser, a developing treatment was performed using 0.21 N TMAH developing liquid to form a contact hole pattern having a diameter of 150 nm (see FIG. 3).

Next, a resist pattern 105 was irradiated with deep ultraviolet light extracted from an excimer laser and having a wavelength region of 240 to 260 nm, and an acid was generated from an acid forming agent contained in the resist pattern 105. Next, an overcoat film 106 was formed on the resist pattern 105 in the same manner as in the first example (see FIG. 4). Next, the acid was diffused from the resist pattern 105 in the same manner as in the first example, and a portion of the overcoat film 106 at a certain distance from the resist pattern 105 was cross-linked (acid catalyst reaction).

Next, dibutylether was applied to the overcoat film 106 to dissolve and remove a portion of the overcoat film 106 which was not cross-linked, and a contact hole pattern having a diameter of 90 nm was formed in the same manner as in the first example (see FIG. 5).

Next, the lower-layer resist film 103 was etched to obtain a lower-layer resist film pattern 108 in the same manner as in the first example (see FIG. 6). Consequently, the lower-layer resist film pattern 108 could be worked with good anisotropy as shown in FIG. 6.

Next, the film 102 to be worked was etched, and a contact hole having a diameter of 90 nm was formed in the film 102 to be worked in the same manner as in the first example (see FIG. 7).

In the present second example, since the overcoat film 106 is formed into a certain thickness on the surface of the resist pattern 105, it is possible to resolve a space pattern which is narrow as much and which cannot be resolved by the exposure. It is possible to work the lower-layer resist film pattern 108 by use of the overcoat film pattern 107 as an etching mask while securing a sufficient etching selective ratio. As a result, it is possible to transfer the resist pattern to the lower-layer resist film 103 having a film thickness required for etching the film 102 to be worked. Even when the film thickness of a resist of the resist pattern 105 is set to be as thin as, for example, 150 nm in order to obtain an exposure margin as in the second example, the film 102 to be worked can be worked.

According to the present embodiment, there can be provided a pattern forming method and a method of manufacturing a semiconductor device in which it is possible to form a space or a hole pattern that is finer than an optical image formed in a resist pattern, and it is possible to work a film to be worked, even when a resist film thickness is reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

What is claimed is:

1. A pattern forming method comprising:
forming a first resist film on a film to be worked formed on a semiconductor substrate;
forming a second resist film on the first resist film;
forming a resist pattern from the second resist film;
forming an overcoat film containing a metal element or a semi-conductive element on the resist pattern;
insolubilizing, in a predetermined solvent, a portion of the overcoat film at a predetermined distance from an interface between the overcoat film and the resist pattern;
removing, with the solvent, a portion of the overcoat film soluble in the solvent to form an overcoat film pattern;
transferring the overcoat film pattern to the first resist film to form a lower-layer resist film pattern; and
transferring the lower-layer resist film pattern to the film to be worked to form a pattern on the film to be worked.

2. The pattern forming method according to claim 1, wherein the insolubilizing is performed by a cross-linking reaction.

3. The pattern forming method according to claim 2, wherein the cross-linking reaction proceeds by an acid catalyst reaction.

4. The pattern forming method according to claim 3, wherein the acid catalyst reaction proceeds by an acid generated from the resist pattern.

5. The pattern forming method according to claim 1, wherein the insolubilizing includes a heating treatment.

6. The pattern forming method according to claim 5, further comprising:
generating acid from an photo-acid-generating agent contained in the resist before the heating treatment.

7. The pattern forming method according to claim 1, wherein the lower-layer resist film pattern is formed by use of a dry etching process using a source gas containing one of an oxygen atom, a nitrogen atom, and a chlorine atom.

8. The pattern forming method according to claim 7, wherein a hydrogen molecule or a molecule containing sulfur is added to the source gas.

9. The pattern forming method according to claim 1, wherein a film thickness of the first resist film is in a range of 20 to 5000 nm.

10. The pattern forming method according to claim 1, wherein a anti-reflection film is formed on the first resist film.

11. The pattern forming method according to claim 1, wherein a film thickness of the second resist film is in a range of 10 to 10000 nm.

12. The pattern forming method according to claim 1, wherein a anti-reflection film is formed on an upper layer of the second resist film.

13. The pattern forming method according to claim 1, wherein a anti-static film is formed on an upper layer of the second resist film.

14. The pattern forming method according to claim 1, wherein the overcoat film is formed by coating the resist pattern with a solution formed by dissolving in an organic solvent a compound having a metal element or a semi-conducting element having a substituent cross-linked with acid.

15. The pattern forming method according to claim 14, wherein the organic solvent is a ketone-based solvent, a cellosolve-based solvent, an ester-based solvent, an ether-based solvent, or an alcohol-based solvent.

16. The pattern forming method according to claim 1, wherein a content of the metal or semi-conducting element is in a range of 2 to 80 wt % in a solid component of a chemical.

17. The pattern forming method according to claim 1, wherein the overcoat film pattern is formed by dissolving and removing a portion of the overcoat film which is not cross-linked using an organic solvent.

18. The pattern forming method according to claim 17, wherein the organic solvent is a ketone-based solvent, a cellosolve-based solvent, an ester-based solvent, an ether-based solvent, or an alcohol-based solvent.

19. The pattern forming method according to claim 1, wherein a certain thickness of the overcoat film pattern floats in a surface and outer periphery of the resist pattern.

20. A method of manufacturing a semiconductor device, comprising:
forming a first resist film on a film to be worked formed on a semiconductor substrate;
forming a second resist film on the first resist film;
forming a resist pattern from the second resist film;
forming an overcoat film containing a metal element or a semi-conducting element on the resist pattern;
insolubilizing, in a predetermined solvent, a portion of the overcoat film at a predetermined distance from an interface between the overcoat film and the resist pattern;
removing, with the solvent, a portion of the overcoat film soluble in the solvent to form an overcoat film pattern;
transferring the overcoat film pattern to the first resist film to form a lower-layer resist film pattern; and
transferring the lower-layer resist film pattern to the film to be worked to form a pattern on the film to be worked, whereby manufacturing the semiconductor device.
